(19) United States
(12) Patent Application Publication
(10) Pub. No.: US 2022/0231785 A1
(43) Pub. Date: Jul. 21, 2022

(54) PERMUTATION SELECTION FOR DECODING OF ERROR CORRECTION CODES

(71) Applicants: Ramot at Tel-Aviv University Ltd., Tel Aviv (IL); Bar-Ilan University, Ramat-Gan (IL)

(72) Inventors: Yair BEERY, Tel-Aviv (IL); Nir RAVIV, Tel-Aviv (IL); Tomer RAVIV, Tel-Aviv (IL); Jacob GOLDBERGER, Tel-Aviv (IL); Avi CACIULARU, Tel-Aviv (IL)

(73) Assignees: Ramot at Tel-Aviv University Ltd., Tel-Aviv (IL); Bar-Ilan University, Ramat-Gan (IL)

(21) Appl. No.: 17/571,659

(22) Filed: Jan. 10, 2022

Related U.S. Application Data
(60) Provisional application No. 63/135,638, filed on Jan. 10, 2021.

(51) Int. Cl. H04L 1/00

(52) U.S. Cl. CPC H04L 1/0045

(57) ABSTRACT

Disclosed herein is a neural network based pre-decoder comprising a permutation embedding engine, a permutation classifier each comprising one or more trained neural networks and a selection unit. The permutation embedding engine is trained to compute a plurality of permutation embedding vectors each for a respective one of a plurality of permutations of a received codeword encoded using an error correction code and transmitted over a transmission channel subject to interference. The permutation classifier is trained to compute a decode score for each of the plurality of permutations expressing its probability to be successfully decoded based on classification of the plurality of permutation embedding vectors coupled with the plurality of permutations. The selection unit is configured to output one or more selected permutations having a highest decode score. One or more decoders may be then applied to recover the encoded codeword by decoding the one or more selected permutations.

### RELATED APPLICATION(S)

This application claims the benefit of priority under 35 USC § 119(e) of U.S. Provisional Patent Application No. 63/135,638 filed on Jan. 10, 2021, the contents of which are incorporated by reference as if fully set forth herein in their entirety.

### FIELD AND BACKGROUND OF THE INVENTION

The present invention, in some embodiments thereof, relates to training neural networks to pre-process encoded codewords transmitted over a transmission channel prior to decoding, and, more specifically, training neural networks to pre-process encoded codewords transmitted over a transmission channel and selecting permutations for decoding which are determined to have highest probability to be successfully decoded.

Transmission of data over transmission channels, either wired and/or wireless is an essential building block for most modern era data technology applications, for example, communication channels, network links, memory interfaces, components interconnections (e.g. bus, switched fabric, etc.) and/or the like.

However, such transmission channels are typically subject to interferences such as, noise, crosstalk, attenuation, etc. which may degrade the transmission channel performance for carrying the communication data and may lead to loss of data at the receiving side.

One of the most commonly used methods to overcome this is to encode the data with error correction data which may allow the receiving side to detect and/or correct errors in the received encoded data. Such methods may utilize one or more error correction models as known in the art, for example, linear block codes such as, for example, algebraic linear code, polar code, Low Density Parity Check (LDPC) and High Density Parity Check (HDPC) codes as well as non-block codes such as, for example, convolutional codes and/or non-linear codes, such as, for example, Hadamard code.

In parallel, research, use and deployment of machine learning and Deep Learning (DL) methods has increased dramatically in recent years and demonstrate significant improvements in various applications and tasks including in the field of error correction codes

### SUMMARY OF THE INVENTION

It is an object of the present invention to provide, methods, systems and software program products for effectively decoding liner error correction codes. The foregoing and other objects are achieved by the features of the independent claims. Further implementation forms are apparent from the dependent claims, the description and the figures.

According to a first aspect of the present invention there is provided a neural network based pre-decoder, comprising a permutation embedding engine comprising one or more neural networks trained to compute a plurality of permutation embedding vectors each for a respective one of a plurality of permutations of a received codeword encoded using an error correction code and transmitted over a transmission channel subject to interference, a permutation classifier comprising one or more neural networks trained to compute a decode score for each of the plurality of permutations based on classification of the plurality of permutation embedding vectors coupled with the plurality of permutations, the decode score expressing a probability of the respective permutation to be successfully decoded, and a selection unit configured to output one or more selected permutations of the plurality of permutations of the received codeword having a highest decode score. Wherein one or more decoders are applied to recover the encoded codeword by decoding the one or more selected permutations.

According to a second aspect of the present invention there is provided a computer implemented method of using a trained neural network based pre-decoder to decode codes transmitted over transmission channels subject to interference, comprising:
Receiving a codeword encoded using an error correction code and transmitted over a transmission channel subject to interference.
Applying a trained neural network based pre-decoder to the encoded codeword, the trained neural network based pre-decoder is configured to compute a plurality of permutation embedding vectors each for a respective one of a plurality of permutations of the encoded codeword, compute a decode score for each of the plurality of permutations based on classification of the plurality of permutation embedding vectors coupled with the plurality of permutations, the decode score expressing a probability of the respective permutation to be successfully decoded, and output one or more selected permutations of the plurality of permutations having a highest decode score.
Applying one or more decoders to recover the encoded codeword by decoding the one or more selected permutations.

According to a third aspect of the present invention there is provided a computer implemented method of training a neural network based pre-decoder for preprocessing error correction codes transmitted over transmission channels subject to interference, comprising using one or more processors for:
Receiving a plurality of permutations of one or more training codewords encoded using an error correction code and transmitted over a transmission channel subject to interference. Each of the plurality of permutations is associated with a respective label associating the respective permutation with the one or more training encoded codewords and indicating whether it was successfully decoded.
Training a neural network based pre-decoder to select one or more permutations of the one or more encoded codewords having highest probability to be successfully decoded by applying the neural network based pre-decoder to preprocess the one or more training encoded codeword by:
   Computing a plurality of permutation embedding vectors each for a respective one of the plurality of permutations of the one or more training encoded codewords.
   classifying the plurality of permutation embedding vectors coupled with the plurality of permutations to compute a decode score for each of the plurality of permutations. The decode score expressing a probability of the respective permutation to be successfully decoded.
   Outputting one or more selected permutations of the plurality of permutations having a highest decode score. Wherein the neural network based pre-decoder adjusts according to a match between the one or more selected permutations and their respective labels; and
Outputting the trained neural network based pre-decoder for selecting one or more of a plurality of permutations of one or more encoded codewords for decoding by one or more decoders.

In a further implementation form of the first, second and/or third aspects, the permutation embedding engine comprises one or more self-attention layers and heads followed by a pooling layer.

In an optional implementation form of the first, second and/or third aspects, the one or more self-attention layers and heads compute the plurality of permutation embedding vectors based on node embeddings of at least some of a plurality of nodes of a graph representation of the error correction code.

In a further implementation form of the first, second and/or third aspects, the node embeddings are computed by a neural network based node embedding model constructed based on graph representation of the error correction code, the neural network based node embedding model comprises a plurality of nodes and a plurality of edges connecting the plurality of nodes, each of the plurality of edges having a source node and a destination node is assigned with a respective weight adjusted during the training of the neural network based node embedding model.

In a further implementation form of the first, second and/or third aspects, the graph representation is a member of a group comprising: a bipartite graph, a Tanner graph and/or a factor graph.

In a further implementation form of the first, second and/or third aspects, the permutation embedding engine comprising the one or more self-attention layers and heads is trained to compute the plurality of permutation embedding vectors for the plurality of permutations based on a learned distance distribution among the plurality of permutations.

In a further implementation form of the first, second and/or third aspects, the permutation classifier is further configured to classify the plurality of permutation embedding vectors according to one or more additional features of the error correction code. The one or more additional features are members of a group comprising: Hamming distance, a permuted syndrome and/or an absolute value of the log likelihood ratio (LLR) of the received encoded codeword.

In a further implementation form of the first, second and/or third aspects, the permutation classifier further comprises a multi-class classifier configured for simultaneously classifying at least a subset of the plurality of permutations in a single cycle.

In an optional implementation form of the third aspect, the neural network-based pre-decoder is trained to classify the plurality of permutation embedding vectors according to one or more additional feature of the error correction code. The one or more additional feature is a member of a group comprising: Hamming distance, a permuted syndrome and an absolute value of the log likelihood ratio (LLR) of the one or more training encoded codewords.

In an optional implementation form of the third aspect, the neural network-based pre-decoder is trained to classify the plurality of permutation embedding vectors according to weights assigned to the plurality of permutations based on knowledge base information relating to the code.

In a further implementation form of the third aspect, the neural network based pre-decoder is trained to classify the plurality of permutation embedding vectors according to learned matrices used to map the plurality of permutations to respective decode scores.

In an optional implementation form of the third aspect, the neural network-based pre-decoder is trained to classify the plurality of permutation embedding vectors according to learned biases in the learned parameters matrices.

In a further implementation form of the third aspect, the one or more training encoded codewords encode the zero codeword.

In an optional implementation form of the third aspect, the training further comprising a plurality of training iterations, each iteration comprising selecting another training encoded codeword for training the training the neural network based pre-decoder.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks automatically. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of methods and/or systems as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE SEVERAL VIEWS OF THE DRAWINGS

Some embodiments of the invention are herein described, by way of example only, with reference to the accompanying drawings. With specific reference now to the drawings in detail, it is stressed that the particulars are shown by way of example and for purposes of illustrative discussion of embodiments of the invention. In this regard, the description taken with the drawings makes apparent to those skilled in the art how embodiments of the invention may be practiced.

In the drawings:

FIG. 1 is a schematic illustration of an exemplary neural network based pre-decoder configures to preprocess an encoded error correction code transmitted over a transmission channel, according to some embodiments of the present invention;

FIG. 2 is a schematic illustration of an exemplary permutation embedding engine of a neural network based pre-decoder configured to compute permutation embedding vectors for permutations of the code, according to some embodiments of the present invention;

FIG. 3 is a schematic illustration of an exemplary Tanner Graph of an exemplary error correction code;

FIG. 4 is a schematic illustration of an exemplary permutation classifier of a neural network based pre-decoder comprising a multi-class classifier configured to simultaneously classify a plurality of permutations, according to some embodiments of the present invention;

FIG. 5 is a flowchart of an exemplary process of training a neural network based pre-decoder to preprocess an encoded error correction code and select one or more permutation most probable to be successfully decoded, according to some embodiments of the present invention;

FIG. 6 is a schematic illustration of an exemplary system for training a neural network based pre-decoder to preprocess an encoded error correction code and select one or more permutation most probable to be successfully decoded, according to some embodiments of the present invention;

FIG. 7A and FIG. 7B are graph charts of BER results vs. SNR for BCH(31,16) and BCH(63,36) codes decoded based on permutations selected by a neural network based pre-decoder vs. decoding based on legacy permutation selection, according to some embodiments of the present invention;

FIG. 8 is a graph chart of BER results BER results vs. SNR for top-k evaluations of BCH(63,45) code decoded based on permutations selected by a neural network based pre-decoder, according to some embodiments of the present invention;

FIG. 9 is a graph chart of BER results vs. SNR for several BCH codes decoded based on permutations selected by a neural network based pre-decoder vs. legacy permutation selection for top-k evaluations, according to some embodiments of the present invention;

FIG. 10 is a graph chart presenting distributions of variable nodes of BCH(63,36), BCH(63,45) and BCH(127,64) codes encoded using cycle-reduced and systematic parity-check matrices and applied with a neural network based pre-decoder, according to some embodiments of the present invention;

FIG. 11A, FIG. 11B and FIG. 11C are graph charts of BER results vs. SNR for BCH(31,16) and BCH(63,36) codes BCH(63,36), BCH(63,45) and BCH(127,64) codes encoded using cycle-reduced and systematic parity-check matrices and decoded based on permutations selected by a neural network based pre-decoder, according to some embodiments of the present invention; and

FIG. 12 is a graph chart of BER results BER results vs. SNR for a BCH(63,45) code decoded based on permutations selected by a neural network based pre-decoder trained in several training iterations, according to some embodiments of the present invention.

### DESCRIPTION OF SPECIFIC EMBODIMENTS OF THE INVENTION

The present invention, in some embodiments thereof, relates to training neural networks to pre-process encoded codewords transmitted over a transmission channel prior to decoding, and, more specifically, training neural networks to pre-process encoded codewords transmitted over a transmission channel and selecting permutations for decoding which are determined to have highest probability to be successfully decoded.

Wired and/or wireless transmission channels are the most basic element for a plurality of data transmission applications, for example, communication channels, network links, memory interfaces, components interconnections (e.g. bus, switched fabric, etc.) and/or the like. However, data transmitted via such transmission channels which are subject to one or more interferences such as, for example, noise, crosstalk, attenuation, and/or the like may often suffer errors induced by the interference.

Error correction codes may be therefore applied for encoding codewords transmitted via transmission channels to enable efficient error detection and correction of errors in the received encoded codewords and increase efficiency of decoders to accurately to correctly recover the transmitted encoded codewords while maintaining high transmission rates.

The error correction codes may include a wide range of error correction models and/or protocols as known in the art, for example, linear block codes such as, for example, algebraic linear code, polar code, Low Density Parity Check (LDPC) code, High Density Parity Check (HDPC) code and/or the like. However, the error correction codes may further include non-block codes such as, for example, convolutional codes and/or non-linear codes as well as non-linear codes such as, for example, Hadamard code and/or the like.

However, decoders used to decode the error correction codes may suffer degraded performance due to one or more limitations and/or features inherent to their construction. For example, some commonly used efficient and robust decoders may apply one or more message passing algorithms, for example, Belief Propagation (BP), weighted Belief Propagation (WBP) and/or the like which may operate by passing messages over nodes of a graph representation of the error correction code, for example, a bipartite graph such as, for example, tanner graph, factor graph and/or the like.

The message passing decoding algorithms may be trained until convergence or a maximum number of iterations is reached. However, such message passing decoding algorithms may often and typically include cycles in the graph representation where one or more subsets of nodes may be connected to each other and inducing a closed-loop with every edge appearing once. Such cycles may have a major impact on the decoding efficiency of the message passing decoding algorithms and may significantly reduce the decoding performance messages propagated along cycles may become correlated after several BP iterations which may prevent convergence to the correct posterior distribution thus reducing overall decoding performance.

As known in the art, one highly efficient method of overcoming the cycles effect and enhancing convergence of the message passing decoding algorithms may be applying the message passing decoding algorithms to decode permutations of the received encoded codeword rather than the encoded codeword itself.

In such case, the decoder may apply the message passing decoding algorithm(s) on a permuted received codeword and then apply the inverse permutation on the decoded word to recover the data message encoded in the encoded codeword. This may be viewed as applying the message passing decoding algorithms on the originally received codeword with a different parity-check matrix.

According to some embodiments of the present invention, there are provided methods and systems for training and deploying neural network based pre-decoders configured to select one or more permutations of received encoded codewords having highest probability to be successfully decoded by decoders.

The neural network based pre-decoders may employ one or more neural network architectures, specifically Deep Learning (DL) neural networks, for example, a Fully Connected (CF) neural network, a Convolutional Neural Network (CNN), a Feed-Forward (FF) neural network, a Recurrent Neural Network (RNN) and/or the like.

The neural network based pre-decoder may be therefore trained and deployed in front of the decoder to receive the encoded codewords which are encoded according to the error correction code and transmitted via the transmission channel. It should be noted that the neural network based pre-decoder may be deployed to support practically any type of decoder employing any decoding algorithm.

The neural network based pre-decoder may pre-process the encoded codewords and compute a decode score for one or more permutations of each received encoded codeword indicative of a probability of the respective permutation to be successfully decoded by decoder and may select one or more permutations having highest decode score and output them to the decoder for decoding.

The neural network based pre-decoder may comprise two main modules, a permutation embedding engine (perm2vec) and a permutation classifier each constructed using one or more neural networks.

The permutation embedding engine may be configured and trained to compute a plurality of permutation embedding vectors for a plurality of permutations of the received encoded codeword. Specifically, the permutation embedding engine may be trained to compute the permutation embedding vectors for each received encoded codeword based on the permutations associated with the respective encoded codeword.

The neural network(s) of the permutation embedding engine may include one or more self-attention sublayers and heads followed by pooling layer(s) in order to adjust, adapt and/or otherwise learn the neural network to focus on the most relevant parts of the input.

The permutation embedding engine may compute the permutation embedding vectors also based on node embeddings expressing the structure of the graph representation of the error correction code used to encode the received encoded codeword. The node embeddings may be computed by one or more node embedding models (node2vec) which may be also based on one or more trained neural networks.

Optionally, the permutation embedding engine may compute the permutation embedding vectors also based on one or more features of the error correction code, for example, a permuted syndrome (pattern) representing an error pattern of the received codeword, an estimated Hamming Distance indicating positions of bits different in the permutation, Log-Likelihood Ratios (LLR) of the received encoded codeword and/or the like.

The permutation embedding vectors computed by the permutation embedding engine may be then driven into the permutation classifier together with the permutations and the syndrome (pattern) generated for the received encoded codeword.

The permutation classifier may be trained and configured to classify each of the permutations based on the respective permutation embedding vector(s) and the syndrome and may compute a decode score for each permutation accordingly which is indicative of a probability for the respective permutation to be successfully decoded by the decoder.

One or more permutations having highest decode scores, i.e., estimated with highest confidence to be successfully decoded by the decoder may be selected and output and forwarded to the decoder which may decode the permutation and, based on the decoded permutation, recover the data originally encoded in the encoded codeword.

As stated hereinbefore, any decoder employing practically any decoding algorithm may take advantage and increase its decoding performance by decoding the highest decoding probability permutations specifically selected by the neural network based pre-decoder according to their computed decode scores.

The neural network based pre-decoder may be trained in one or more offline supervised training sessions using one or more training datasets comprising a plurality (prior to deployment) of training permutations of one or more encoded codewords. Each of the training permutations may be labeled to associate it with a respective encoded codeword and further indicate whether the respective training permutation was successfully decoded by the decoder. The neural network based pre-decoder may therefore learn, evolve and/or adjust according to a match and/or comparison between the decode score computed for each permutation estimated to be successfully decoded and its respective label.

Optionally, the neural network based pre-decoder may be further trained online (after deployment).

Applying the trained neural network based pre-decoder may present major advantages and benefits compared to currently existing error correction code based decoding methods and systems.

First, decoding permutations of encoded codewords rather than the encoded codewords themselves in order to recover the encoded data (message) as may be done by the existing methods may significantly increase decoding performance of the decoder. The performance increase may be expressed, for example, by increased decoding accuracy, reliability and/or consistency. In another example, the performance increase may be expressed by reduced decoding time. In another example, the performance increase may be expressed by reduced resource consumption (utilization), for example, reduced processing resources (processing power), reduced storage resources, reduced power consumption and/or the like.

Moreover, while some of the existing methods may apply the decoder to decode permutations of the received encoded codewords, such methods may typically apply the decoder to decode all of the permutations associated with the received encoded codeword. Decoding all the permutations in a plurality of decode runs may be extremely resource intensive, for example, in terms of increased computing resource utilization, increased decoding time, increased power consumption and/or the like. This limitation may also limit and potentially completely prevent scaling to large and/long error correction blocks where the magnitude of permutations may lead to practically inability to decode all the associated permutations.

This limitation, namely the large number of decoded permutations, may be overcome by deploying the neural network based pre-decoder since a subset comprising only of a very small number, optionally one, of the highest scoring permutations may be selected and driven to the decoder. Reducing the number of decoded operations to only a few (e.g. less than 5) and optionally to only one highest scoring permutation may therefore significantly reduce the resource consumption of the decoder, reduce decoding time, and support unlimited scaling. Moreover, decoding accuracy of the decoder may not be affected and/or degraded since the selected highest scoring permutations having the highest decode score among all permutations are estimated, with the highest probability among all permutations, to be successfully decoded by the decoder.

Furthermore, using the node embeddings to compute the permutation embedding vectors which are used to classify the permutations and score them accordingly (i.e., compute the decode score) may significantly increase the accuracy of the computed decode scores and selection of the highest scoring permutation since the node embeddings may enable the permutation classifier to account for the structure and layout of the error correction code. Accurately selecting the highest scoring permutation(s) may in turn significantly increase the decoding performance and/or accuracy of the decoder.

In addition, configuring the permutation classifier to classify the permutations based on one or more of the features of the error correction code may further increase accuracy of the computed decode scores and selection of the highest scoring permutation since the permutation classifier may further take into consideration specific features of the specific error correction code used to encode the encoded codeword.

Also, further training the neural network based pre-decoder online after deployed to pre-process encoded codewords transmitted via a certain transmission channel may enable the neural network based pre-decoder to further adapt, adjust and/or learn one or more parameters and/or characteristics specific to the certain transmission channel, for example, interference and/or noise patterns. By adapting to the specific transmission, the neural network based pre-decoder may select the highest scoring permutation(s) with increased accuracy which in turn may further increase the decoding performance of the decoder decoding the selected permutation(s).

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer program code comprising computer readable program instructions embodied on a computer readable medium may be transmitted using any appropriate medium, including but not limited to wireless, wire line, optical fiber cable, RF, etc., or any suitable combination of the foregoing.

The computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

The computer readable program instructions for carrying out operations of the present invention may be written in any combination of one or more programming languages, such as, for example, assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages.

The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

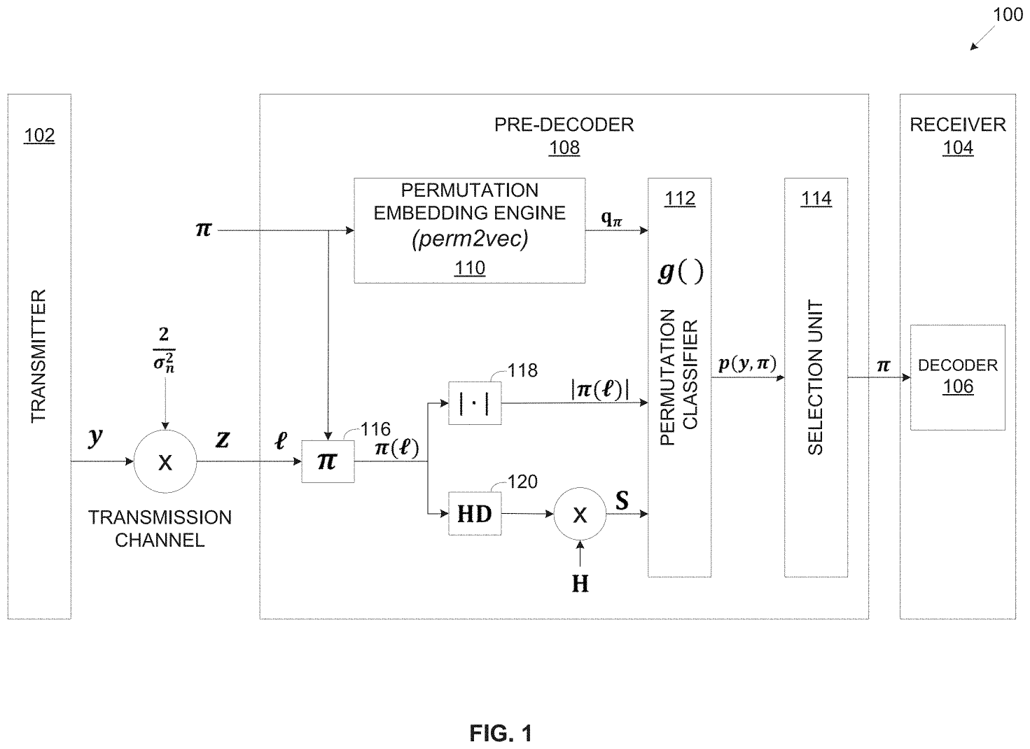

Referring now to the drawings, FIG. 1 illustrates a schematic illustration of an exemplary neural network based pre-decoder configures to preprocess an encoded error correction code transmitted over a transmission channel, according to some embodiments of the present invention.

An exemplary transmission system 100 may include a transmitter (encoder 102) which may transmit data (messages) via a transmission channel which may comprise one or more wired and/or wireless transmission channels deployed for one or more of a plurality of applications, for example, communication channels, network links, memory interfaces, components interconnections (e.g. bus, switched fabric, etc.) and/or the like.

In particular, the transmission channel may be typically subject to one or more interferences, for example, noise, crosstalk, attenuation, and/or the like which may induce one or more errors into the transited data. Therefore, in order to overcome data corruption induced by the interference(s), the transmitter 102 transmitting the data according to one or more transmission and/or encoding algorithms and/or protocols may further encode the data according to one or more error correction code models and/or protocols as known in the art to support error detection and/or correction.

The error correction codes, may include, for example, linear block codes such as, for example, algebraic linear code, polar code, LDPC code, HDPC code and/or the like. However, the error correction codes may further include non-block codes such as, for example, polar codes, convolutional codes and/or the like and also non-linear codes such as, for example, Hadamard code and/or the like.

While in typical transmission systems, the encoded codewords (data messages) transmitted by the transmitter 102 via the transmission channel may be received by a receiver 104 comprising one or more decoders 106 configured to decode the received encoded codewords, in the transmission system 100, the encoded codewords may be received by a pre-decoder 108 deployed between the transmission channel and the decoder 108.

The pre-decoder 108 which may be optionally integrated in the receiver 104 may be and configured to preprocess the data received from via transmission channel and output (drive) corresponding data to the decoder 106 which may decode it to recover the data messages transmitted by the transmitter 102.

In particular, the pre-decoder 108 may be a neural network based pre-decoder 108 comprising one or more trained neural networks as known in the art, in particular one or more Deep Learning (DL) neural networks, for example, a CF neural network, a CNN, an FF neural network, an RNN and/or the like.

In a typical communication system, first, a length k binary message m∈{0,1}^{k} may be encoded at the transmitter 102 according to one or more error correction codes using a generator matrix G into a length n codeword c=G^{T}m∈{0,1}ⁿ. Every codeword c satisfies Hc=0, where H is the parity-check matrix uniquely defined by GH^{T}=0. The encoded codeword c may be then modulated according to one or more modulation schemes, for example, Binary Phase Shift Keying (BPSK) mapping (0→1,1→−1), Quadrature Phase Shift Keying (QPSK) and/or the like resulting in a modulated word x. During transmission through the transmission channel subject to one or more of the interferences, for example, an Additive White Gaussian Noise (AWGN) defined by

$$\frac{2}{{σ}_{z}^{2}}$$

may be added to the transmitted encoded codeword. The encoded codeword which in the typical transmission system may be received at the decoder 106 may be defined by y=x+z, where z˜N(0, σ₂²Iₙ) wherein Iₙ is an identity matrix of size n with 1's in its main diagonal and 0's elsewhere.

The decoder 106 may check each received encoded codeword z in order to identify one or more detectable errors in the encoded codeword. For that purpose, the decoder 106 may calculate an estimated codeword ĉ using one or more Hard Decision (HD) rules, for example, ĉᵢ=1_{{y}_{ᵢ}_{<0}}. In case a syndrome s=Hĉ representing an error pattern of the received encoded codeword is all zeros meaning that no error is detected in the received encoded codeword, the decoder 106 may output ĉ and conclude. However, a non-zero syndrome s may indicate that one or more errors occurred during transmission via the transmission channel and are detected in the received encoded codeword.

The decoder 106 may apply one or more decoding functions and/or algorithms designated dec: y→{0,1}ⁿ to decode the output ĉ in order to recover the originally transmitted codeword y. The decoding algorithm dec( ) may utilize any one or more decoding technologies, algorithms, and/or architectures. One such decoding algorithm is soft-decision Belief Propagation (BP) as known in the art. The BP is a graph-based message passing inference algorithm which may be used to decode corrupted codewords in an iterative manner, working over a graph representation of the error correction code applied to encode the codeword at the transmitter 102, for example, a bipartite graph such as, for example, a Tanner graph, a factor graph and/or the like. For brevity, the description herein after may refer to the Tanner graph, this however should not be construed as limiting since other graphs may be used.

The BP algorithm operates by passing messages over nodes of the Tanner graph until convergence or a maximum number of iterations is reached. One property known to affect the convergence of the BP algorithm is cycles. Cycles in a Tanner graph refer to a subset of nodes connected to each other and inducing a closed-loop with every edge appearing once. Messages that are propagated along cycles may become correlated after several BP iterations which may prevent convergence to the correct posterior distribution and may thus reduce overall decoding performance.

As stated herein before, in contrast to the typical transmission system where the encoded codewords (messages) transmitted by the transmitter 102 via the transmission channel are received at the decoder 106 of the receiver 104, in the transmission system 100, the neural network based pre-decoder 108 may receive the encoded codewords from the transmission channel.

The neural network based pre-decoder 108 may preprocess the received encoded codewords in order to identify and select one or more permutations of the code having highest probability to be successfully decoded by the decoder 106 since, as known in the art, one possible way to mitigate the detrimental effects of cycles in the BP algorithm may be by using code permutations.

The decoder 106 may therefore apply the BP algorithm on the permuted received codeword and then apply the inverse permutation on the decoded word to recover the data message encoded in the encoded codeword. This can be viewed as applying the BP algorithm on the originally received codeword with a different parity-check matrix. Since there are cycles in the Tanner graph there is no guarantee that the BP algorithm will converge to an optimal solution multiple permutation may be used in a plurality of different decoding attempts which may yield better convergence and overall decoding performance gains as known in the art and observed in the experiments presented hereinafter.

Let π be a permutation represented by n indices {1, . . . , n}. A permutation of a codeword c=(c₁, . . . , cₙ) may be defined by exchanging positions of the entries of c as expressed in equation 1 below.

π(c)=(c_{π(1)},c_{π(2)}, . . . ,c_{π(n)})^{T} Equation 1:

For example, a first permutation may be the identity permutation represented by the following order of the indices, 1, 2, 3, . . . , n. Another permutation represented by another order of indices, for example, 2, 1, 3, . . . , n, is a permutation in which the 1^{st} and 2^{nd} indices are flipped.

A permutation π is an automorphism of a given error correction code C if c∈C implies π(c)∈C. The group of all automorphism permutations of a code C is denoted Aut(C), also referred to as the Permutation Group (PG) of the code.

For example, the PGs of BCH codes which is a widely and commonly employed family of codes may be expressed by equation 2 below.

π_{α,β}(i)=[2^{α}·i+β](mod n) Equation 2:

where α∈{1, . . . , log₂(n+1)} and β∈{1, . . . , n},

thus, a total of n log₂(n+1) permutations compose Aut(C) of the BCH.

In attempt to decode a received word y encoded using the error correction code C, picking a permutation from the PG Aut(C) may therefore result in improved decoding performance and/or capabilities. However, executing the decoding algorithm for each permutation within the PG of the error correction code may require extreme computing resources (e.g., processing resources, storage resources, etc.) and/or time and may be thus a computationally prohibitive task, especially if the PG of the error correction code C is large.

In order to reduce the processing resources and achieve a feasible decoding scheme, an alternative approach may be applied in which a subset of one or more best permutation estimated to yield best decoding performance may be first selected and provided to the decoder 106 such that only the selected permutation may be decoded thus significantly reducing computing resources consumption.

Given a received word y, an optimal single permutation π*∈Aut(C) is the permutation which minimizes the Bit Error Rate (BER) as expressed in equation 3 below.

π*=arg min_{π∈Aut(C)}BER(π⁻¹(dec(π(y))),c) Equation 3:
where dec( ) is the decoding algorithm, c is the submitted codeword and BER is the Hamming distance between binary vectors.

The solution to equation 3 may be intractable since the correct codeword may be unknown during the decoding process. In order to overcome this limitation, the neural network based pre-decoder 108 may be configured to apply an approximate solution and select a subset comprising one or more best permutation of the PG which are estimated to yield best decoding performance at the decoder 106 without applying a tedious decoding process for each code permutation and without relying on the correct codeword c.

The neural network based pre-decoder 108, which may be interchangeably designated Graph Permutation Selection (GPS) hereinafter, may comprise a permutation embedding engine 110 interchangeably designated perm2vec herein after, a permutation classifier 112 interchangeably designated g( ) herein after and a selection unit 114.

The perm2vec permutation embedding engine 110 constructed of one or more neural networks may receive a permutation it, and outputting a permutation embedding vector q_{π}. In particular, the permutation embedding engine 110 may be implemented using one or more neural trained networks.

The neural network(s) of the perm2vec permutation embedding engine 110 may comprise an input layer, an output layer, an embedding layer, and a plurality of hidden layers each comprising a plurality of nodes and a plurality of edges connecting the plurality of nodes. Each of the plurality of edges has a source node and a destination node and is assigned with a respective weight adjusted during training of the perm2vec permutation embedding engine 110.

The perm2vec permutation embedding engine 110 may further comprise one or more sublayers, for example, two sublayers, a self-attention layer followed by an average pooling layer.

Moreover, the perm2vec permutation embedding engine 110 may compute the permutation embedding vectors q_{π} based on node embeddings which may add positional encodings expressing the relations between variable nodes of the graph representation of the error correction code, for example, the Tanner graph thus taking the code structure into consideration and increasing performance of the decoder(s) 106 as demon tared in the experiments described hereinafter.

Optionally, one or more node embedding techniques may be applied for learning the positional node embedding the variable nodes of the Tanner graph representing the error correction code which have been shown to yield better performance than the constant positional encodings.

For example, one or more neural network based embedding models (designated node2vec node embeddings model hereinafter) constructed based on graph representation of the error correction code, for example, the bipartite graphs, the Tanner graph, the factor graph and/or the like may be applied to create the node embeddings.

The node2vec node embeddings model may comprise an input layer, an output layer, an embedding layer, and a plurality of hidden layers each comprising a plurality of nodes corresponding to messages of a message passing algorithm transmitted over a plurality of edges of a bipartite graph representation of the error correction code. Each of the plurality of edges having a source node and a destination node may be assigned with a respective weight adjusted during the training of the neural network based node embedding mode

The node2vec node embeddings model may encode the nodes in the graph representation as low-dimensional vectors that summarize their relative graph position and the structure of their local neighborhood nodes. Each learned vector may correspond to a node in the graph, and as known in the art, in the learned vector space, geometric relations are captured, for example, interactions that are modeled as edges between the nodes in the graph. Specifically, the perm2vec permutation embedding engine 110 may be trained by maximizing the mean probability of the occurrence of subsequent nodes in fixed-length sampled random walks which may employ Breadth-First (BFS) and/or Depth-First (DFS) graph searches to produce high-quality informative node representations.

Attention mechanisms may be applied in neural networks, specifically, in the permutation embedding engine 110 to enable the neural models to focus on the most relevant parts of the input. This modern neural architecture may allow for the use of weighted averaging to optimize a task's objective and to deal with variable-sized inputs. When feeding an input sequence into an attention model, the resulting output is an embedded representation of the input. When a single sequence is fed, the attentive mechanism is employed to attend to all positions within the same sequence. This is commonly referred to as the self-attention representation of a sequence. Initially, self-attention modeling was used in conjunction with Recurrent Neural Networks (RNNs) and Convolutional Neural Networks (CNNs) mostly for natural language processing (NLP) tasks and was shown to produce superior results on multiple automatic machine translation tasks.

An advanced form of modeling attentive relations may include transformer networks which may allow modeling inter-sequence dependencies regardless of the position in the input sequence. Such transformer models applied, for example, in translation models were demonstrated to achieve state-of-the-art performance by solely using this self-attention model. further advancement of the transformer-based self-attentive models employs multiple self-attention layers.

The self-attention is applied in the permutation embedding engine 110 for permutation representation which may enable improved, better and/or richer permutation modeling compared to a non-attentive representation. The rationale behind using self-attention comes from learned permutation distance metrics preservation; a pair of “similar” permutations will have a close geometric self-attentive representation in the learned vector space, since the number of index swaps between permutations only affects the positional embedding additions. In other words, self-attention may be applied to learn and map a distance distribution among the plurality of permutations.

Applying the permutation embedding engine 110, the neural network based pre-decoder 108 may therefore leverage the benefits of the self-attention neural network in physical layer communication systems.

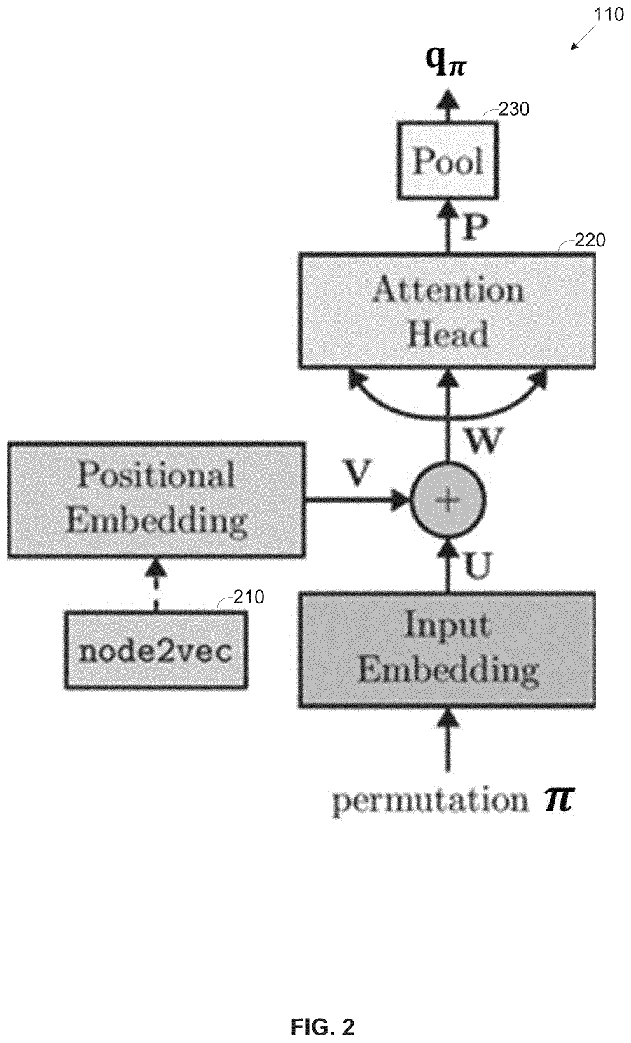

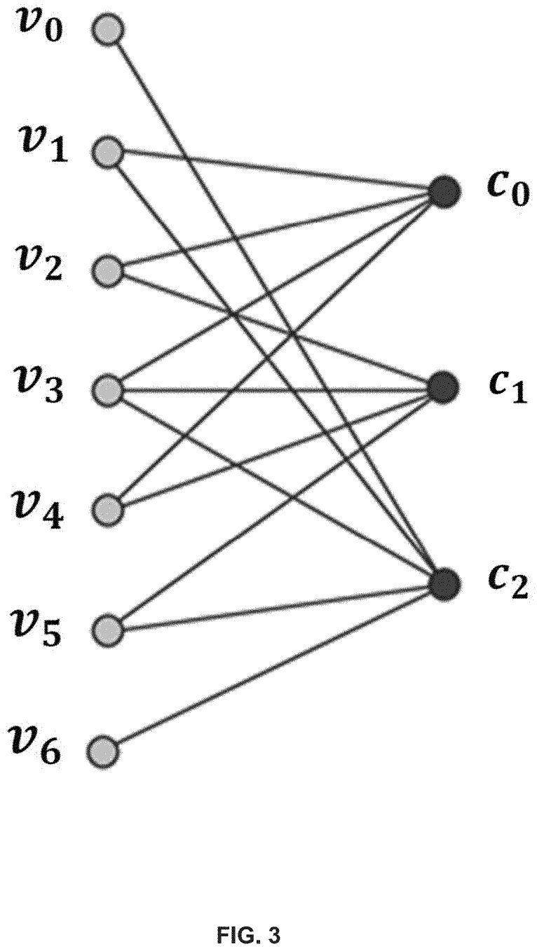

Reference is now made to FIG. 2, which is a schematic illustration of an exemplary permutation embedding engine of a neural network based pre-decoder configured to compute permutation embedding vectors for permutations of the code, according to some embodiments of the present invention. Reference is also made to FIG. 3, which is a schematic illustration of an exemplary Tanner Graph of an exemplary error correction code.

A permutation embedding engine such as the perm2vec permutation embedding engine 110 may use what may be regarded as a dictionary comprising learned positional embeddings which have been shown to yield better performance than the constant positional encodings. The dimension of the output permutation embedding space, which is a hyperparameter set before the node embedding training, may be denote by d_{w}. The embeddings of each index of the permutation π within the block length may be therefore represented by the learned vector of length d_{w}, and denoted as u_{π(i)}. There are n such vectors, each for a respective one of the indices of the error correction code.

However, instead of randomly initializing the positional permutation embeddings, a node2vec node embeddings model 210 as known in the art may be first trained over the corresponding Tanner graph of the error correction code to identify correlations between nodes within the Tanner graph.

The node2vec node embeddings model 210 may be trained during a preprocessing stage over the Tanner graph of the error correction code of length n to learn the representation of each variable node vᵢ thus resulting with n vector representations of length d_{w} for each variable node vᵢ which may serve as variable node embeddings.

The output variable nodes embeddings may then serve as the initial positional permutation embeddings. This may help the neural network based pre-decoder 108 to incorporate some graph structure and use the error correction code information.

It should be noted that other node embedding models may be used and trained instead of the node2vec node embeddings model 210. The self-attention sublayer(s) 220 of the node2vec node embeddings model 210 may employ multiple attention heads, however, for brevity a single attention head is shown. Moreover, it was demonstrated that using one attention head may be sufficient to achieve significantly improved decoding performance results.

The embedding vector of a permutation π(i), i.e., the embedding of the i^{th} index in the permutation it, may be denoted by uᵢ∈R^{d}^{_{w}} and the node embedding of the i^{th} variable node may be denoted by vᵢ∈R^{d}^{_{w}}. It should be noted that both uᵢ and vᵢ are learned, but as stated herein before vᵢ may be initialized according to the output of the node2vec node embeddings model 210 comprising pre-trained variable node embeddings over the error correction code's Tanner graph.

The augmented attention head (attention layer) may then operate on an input vector sequence, W=(w₁, . . . , wₙ) of n vectors where wᵢ∈R^{d}^{_{w}}, wᵢ=uᵢ+vᵢ. The attention head may compute a same-length vector sequence P=(p₁, . . . , pₙ), where pᵢ∈R^{d}^{ₚ}. Each encoder's output vector pᵢ may be computed as a weighted sum of linearly transformed input entries according to equation 4 below.

pᵢ=Σⱼ₌₁ⁿαᵢⱼ(Vwⱼ), Equation 4:
where the attention weight coefficient is computed using a softmax function expressed in equation 5 below of the normalized relative attention between two input vectors wᵢ and wⱼ as expressed in equation 6 below.

$$\begin{matrix}{a}_{i j} = \frac{{e}^{{b}_{i j}}}{{\sum }_{m = 1}^{n} {e}^{{b}_{i m}}} & Equation 5 \\ {b}_{i j} = \frac{{( Q {w}_{i} )}^{T} ( K {w}_{j} )}{\sqrt{{d}_{p}}} & Equation 6\end{matrix}$$

It should be noted that Q, K, V∈R^{d}^{_{w}}^{×d}^{ₚ} are learned parameters matrices mapping the permutations π to respective embedding vectors.

Finally, the vector representation of the permutation π may be computed in a pooling layer 230 by applying the average pooling operation across the sequence of output vectors according to equation 7 below and is output from the perm2vec permutation embedding engine 110 to the permutation classifier 112.

$${q}_{π} = \frac{1}{n} {\sum }_{i = 1}^{n} {p}_{i} \qquad Equation 7$$

The permutation classifier 112 g( ) utilized by one or more trained neural networks, for example, a Neural Multilayer Perceptron (MLP) and/or the like may be configured to predict a probability of successful decoding of a given received codeword y and one or more permutations π represented by a vector q. The permutation classifier 112 g( ) may further compute a decode score p(y,π) for the word π(y) accordingly to express the probability of successfully decoding the permutations π by the decoder 106 applying the decoding algorithm dec( ).

The permutation classifier 112 g( ) may receive the permutations π(y) of the received codeword y, the permutation embedding vector q_{π} computed by the perm2vec permutation embedding engine 110 for the permutations π and the parity check syndrome S computed by applying the parity-check matrix H of the error correction code to the codeword optionally decoded using Hard-Decision Decoder (HDD) 120.

Optionally, rather than receiving the permutations π(y), the permutation classifier 112 g( ) may receive the permutations π(l) of the Log-Likelihood Ratios (LLR) l of the received encoded codeword y, expressing the interference induced by the transmission channel to the received encoded codeword y. For the general case, the LLRs l may be expressed by

$${l}_{v} = log log ( \frac{P ( {y}_{v} )}{P ( {y}_{v} )} )$$

and for the AWGN interference, the LLRs l may be expressed by

$$l = \frac{2}{{σ}_{z}^{2}} \cdot y$$

and knowledge of σ_{z} is assumed.

Specifically, the permutation classifier 112 g( ) may receive an absolute value |π(l)| of the permutations π(l) of the LLRs l computed by applying an absolute value operator 118 to the permutations π(l).

The permutation classifier 112 g( ) may therefore receive absolute value of the permuted input LLRs|π(l)| and the syndrome s∈R^{n-k} of the permuted word π(l)

The permutation classifier 112 g ( ) may use a first linear mapping to obtain l′=Wₗ·π(l) and s′=Wₛ·s respectively, where Wₗ∈R^{d}^{ₚ}^{×n} and Wₛ∈R^{d}^{ₚ}^{×(n-k)} are learned matrices.

The permutation classifier 112 g( ) may apply one or more algorithms and/or computations, for example the formulation shown in equation 8 below.

g(h)=w₄^{T}φ₃(φ₂(φ₁(h)))+b₄ Equation 8:
wherein φ is the number of layers in the permutation classifier g( ) neural network a LeakyReLU activation function as described hereinafter. And where h is defined by equation 9 below.

h=[q;l′;s′;q∘l′;q∘s′;l′∘s′;q−l′;q−s′;l′−s′] Equation 9:

where [⋅] designates concatenation and ∘ designates the Hadamard product.

Each layer i, φᵢ, of the permutation classifier 112 g( ) may be defined according to equation 10 below expressing that the layer φᵢ may be constructed based on the learned parameters matrices and further based on biases learned vectors.

φᵢ(x)=LeakyReLU(Wᵢx+bᵢ) Equation 10:
where W₁∈R^{9d}^{ₚ}^{×2d}^{ₚ}, W₂∈R^{2d}^{ₚ}^{×d}^{ₚ}, W₃∈R^{d}^{ₚ}^{×d}^{ₚ}^{/2} and W₄∈R^{d}^{ₚ}^{/2} are the learned matrices and b₁∈R^{2d}^{ₚ}, b₂∈R^{d}^{ₚ}, b₃∈R^{d}^{ₚ}^{/2} and b₄∈R are the learned biases respectively.

The permutation classifier 112 g( ) may compute the decode score p(y,π) for each permutation according to equation 11 below to express estimated probability for successful decoding π(y) by the decoder 106.

p(y,π)=σ(g(h)) Equation 11:
where 0≤p( )≤1 and g(h) is the last hidden layer and π(⋅) is the sigmoid function.

Optionally, the permutation classifier 112 g( ) may be configured to classify the permutations π for one or more codewords y according to weights assigned to the plurality of permutations π based on knowledge base information relating to the error correction code which may be injected into the permutation classifier 112 g( ).

The knowledge base information may include a-priori information about the permutations' importance, specifically about the decoding performance of each permutation for one or more error correction codes.

For example, for BCH codes all permutations may have equal performance and there is, therefore, no need and/or benefit in providing such information to the permutation classifier 112 g( ). However, for polar codes, some permutations may be known, empirically, to have statistically better performance than other permutations. In such case, providing this knowledge base information with the empirical data to the permutation classifier 112 g( ) may significantly improve the permutation classification since the permutation classifier 112 g( ) may assign weights to the permutations based on their performance, in particular, higher weights for high performing permutations and lower weights for lower-performing permutations.

In another example, the knowledge base information provided to the permutation classifier 112 g( ) may further include one or more features of the error correction code which may further improve the classification of the permutations by the permutation classifier 112 g( ). Such additional features injected to the permutation classifier 112 g( ) may include, for example, the permuted syndrome designated S hereinbefore which represents an error pattern of a received codeword.

In another example, the additional features injected to the permutation classifier 112 g( ) may include estimated Hamming Distance. The Hamming distance between two codewords is the number of positions at which their corresponding bits are different. To compute the Hamming Distance for a given received word, by utilizing any decoder 106, a soft decision may be converted into a hard decision (binary bits) and then the Hamming distance may be computed w.r.t the correct word. One option is to estimate the Hamming distance using a classical HDD 120. It should be noted that while the syndrome S represents an error pattern, the Hamming distance metric represents the number of errors.

In another example, the additional features injected to the permutation classifier 112 g( ) may include an absolute value of the LLR, |l|. The absolute value of the LLRs is a reliability parameter for each bit where the higher the absolute value of the LLR of a bit the better is reliability for correctly decoding the bit.

According to some embodiments of the present disclosure, the permutation classifier 112 g( ) may optionally comprise a multi-class classifier configured for simultaneously classifying at least a subset of the plurality of permutations in a single cycle.

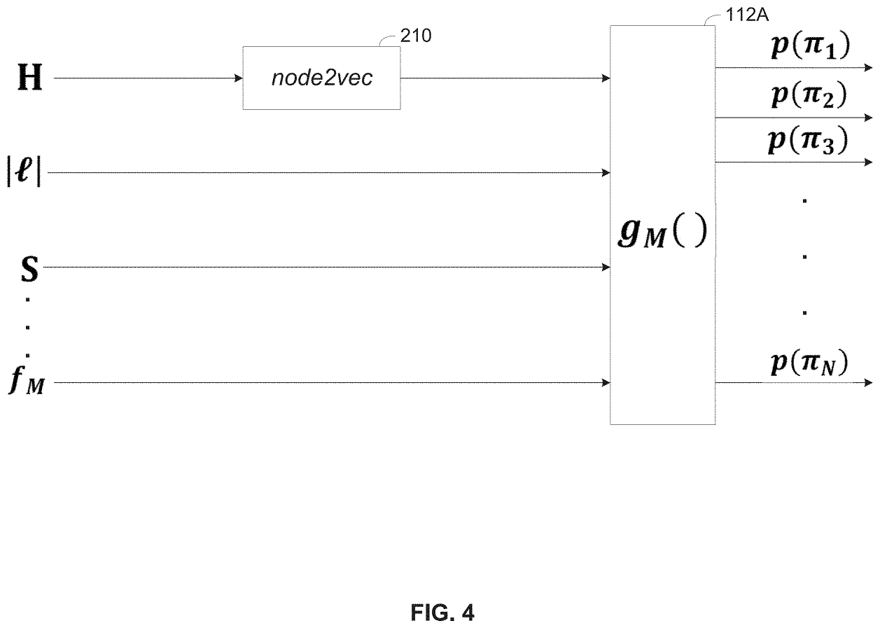

Reference is now made to FIG. 4, which is a schematic illustration of an exemplary permutation classifier of a neural network based pre-decoder comprising a multi-class classifier configured to simultaneously classify a plurality of permutations, according to some embodiments of the present invention.

As seen, a plurality and potentially all of the permutations may be injected into a multi-class permutation classifier 112A g_{M}( ) such as the permutation classifier 112 g( ) which may simultaneously classify the plurality of permutations in a reduced number of cycles. The inputs to the multi-class permutation classifier 112A g_{M}( ) may comprise a plurality (M) of features f_{M}, for example, f₁ may include the parity-check matrix H, f₂ may include the absolute value of the LLR | [symbol] |, f₃ may include the syndrome S and so on.

Optionally, in case the multi-class permutation classifier 112A g_{M}( ) is configured and able to receive all the features described herein before at the same time, then the multi-class permutation classifier 112A g_{M}( ) may classify all of the permutations in a single cycle.

Finally, the selection unit 114 may select a subset of permutations comprising one or more permutations \hat{π} having highest decode score p(y,π), i.e. permutations estimated to have highest probability among all permutations π to be successfully decoded by the decoder 106 applying the decoding algorithm dec( ).

The selection unit 114 may apply one or more methods, schemes and/or algorithms for identifying and selecting the highest decode score permutations \hat{π}. For example, the selection unit 114 may apply the computation described in equation 12 below.

\hat{π}=arg max_{π∈Aut(C)}p(y,π) Equation 12:

Optionally, the selection unit 114 may select the subset of highest scoring permutations π according to one or more selection rules. For example, a certain selection rule may define that the subset should include a certain number of highest scoring permutations, for example, 1, 5, 10 and/or the like. The size of the subset, i.e., the number of selected permutations may be set according to one or more operational parameters, for example, resources availability and computing power available to the decoder 106. In another example, a certain selection rule may define a certain threshold level, for example, 0.85, 0.9, 0.95 and/or the like such that the selection unit 114 may select each permutation π having p exceeding the defined threshold level.

The neural network based pre-decoder 108 may then output the subset of selected permutation(s) \hat{π}. Having the highest decode score.

The receiver 104, specially the decoder 106 may then apply the decoding algorithm dec( ) to decode \hat{π}(y) and produce the decoded word expressed in equation 13 below.

ĉ=\hat{π}⁻¹(dec(\hat{π}(y))) Equation 13:

The complete algorithm executed by the GPS neural network based pre-decoder 108 and the decoder 106 is presented in pseudo-code excerpt 1 below.

### Pseudo-Code Excerpt 1:

| Input : received encoded codeword y | |
|---|---|
| Output : predicted codeword ĉ | |
| 1 | Decoding (y) |
| 2 | for π in Aut(C) do |
| 3 | p(y, π) = GPS(y, π); |
| 4 | end |
| 5 | \hat{π} = arg max_{π}p(y,π); |
| 6 | ĉ = \hat{π}⁻¹ (dec(\hat{π}(y))); |
| 7 | return ĉ |

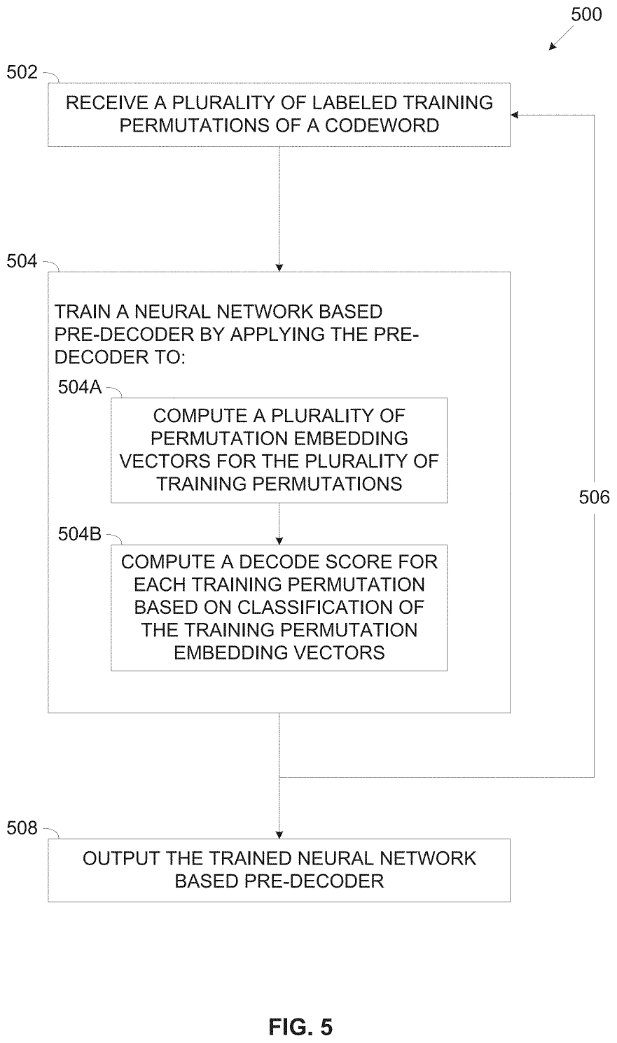

Reference is now made to FIG. 5, which is a flowchart of an exemplary process of training a neural network based pre-decoder to preprocess an encoded error correction code and select one or more permutation most probable to be successfully decoded, according to some embodiments of the present invention.

An exemplary process 500 may be executed to train one or more neural network based pre-decoders such as the neural network based pre-decoder 108 to decode one or more error correction codes, for example, linear block codes such as, for example, algebraic linear code, polar code, LDPC and HDPC codes, non-block codes such as, for example, convolutional codes and/or non-linear codes, such as, for example, Hadamard code.

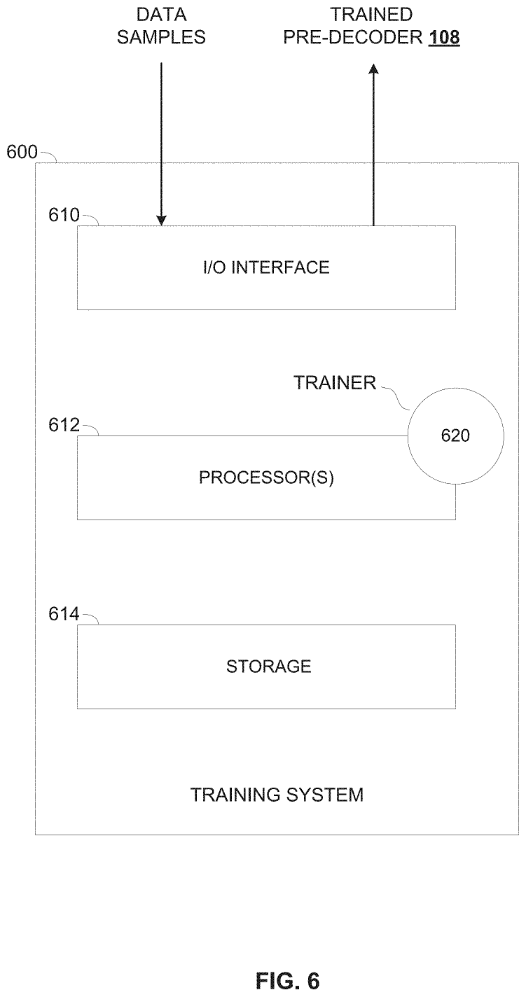

Reference is also made to FIG. 6, which is a schematic illustration of an exemplary system for training a neural network based pre-decoder to preprocess an encoded error correction code and select one or more permutation most probable to be successfully decoded, according to some embodiments of the present invention.

An exemplary training system 600 may comprise an Input/Output (I/O) interface 610, a processor(s) 612 for executing a process such as the process 500 and a storage 614 for storing code (program store) and/or data.

The I/O interface 610 may comprise one or more wired and/or wireless interfaces, for example, a Universal Serial Bus (USB) interface, a serial interface, a Radio Frequency (RF) interface, a Bluetooth interface and/or the like. The I/O interface 610 may further include one or more network and/or communication interfaces for connecting to one or more wired and/or wireless networks, for example, a Local Area Network (LAN), a Wireless Local Area Network (WLAN), a Wide Area Network (WAN), a Municipal Area Network (MAN), a cellular network, the internet and/or the like.

The processor(s) 612, homogeneous or heterogeneous, may include one or more processing nodes arranged for parallel processing, as clusters and/or as one or more multi-core processor(s). The storage 614 may include one or more non-transitory memory devices, either persistent non-volatile devices, for example, a hard drive, a solid state drive (SSD), a magnetic disk, a Flash array and/or the like and/or volatile devices, for example, a Random Access Memory (RAM) device, a cache memory and/or the like. The storage 614 may further include one or more network storage resources, for example, a storage server, a network accessible storage (NAS), a network drive, a cloud storage and/or the like accessible via the network interface 610.

The processor(s) 612 may execute one or more software modules, for example, a process, a script, an application, an agent, a utility, a tool, an Operating System (OS) and/or the like each comprising a plurality of program instructions stored in a non-transitory medium such as the storage 614 and executed by one or more processors such as the processor(s) 612.

The processor(s) 612 may further include, integrate and/or utilize one or more hardware modules (elements integrated and/or utilized in the task management system 200, for example, a circuit, a component, an Integrated Circuit (IC), an Application Specific Integrated Circuit (ASIC), a Field Programmable Gate Array (FPGA), a Digital Signals Processor (DSP), a Graphical Processing Unit (GPU), an Artificial Intelligence (AI) accelerator and/or the like.

The processor(s) 612 may therefore execute one or more functional modules utilized by one or more software modules, one or more of the hardware modules and/or a combination thereof. For example, the processor(s) 612 may execute a trainer 620 functional module for executing the process 500 to train one or more neural network based pre-decoder 108.

Optionally, the training system 600 and/or the trainer 620 may be provided, executed and/or utilized at least partially by using one or more cloud computing services, for example, Infrastructure as a Service (IaaS), Platform as a Service (PaaS), Software as a Service (SaaS) and/or the like provided by one or more cloud infrastructures and/or services such as, for example, Amazon Web Service (AWS), Google Cloud, Microsoft Azure. IBM cloud and/or the like.

Training the neural network based pre-decoder 108 may be done in one or more pre-processing training sessions in which the neural network based modules of the neural network based pre-decoder 108 may be trained, namely a permutation embedding engine such as the perm2vec permutation embedding engine 110 and a permutation classifier such as the permutation classifier 112 g( ).

As shown at 502, the process 500 starts with the trainer 620 receiving a training dataset comprising a plurality of training data samples mapping a plurality of training permutations of one or more training codewords encoded according to an error correction code for which the neural network based pre-decoder 108 is trained. In particular, the training samples may map a plurality of training permutations of encoded codewords transmitted over a transmission channel subject to interference, for example, noise, crosstalk, attenuation and/or the like.

Moreover, the training dataset may compose a plurality of mini-batches each comprising training permutations of respective K received encoded codewords.

Each encoded codeword may be transmitted over the transmission channel subject to interference, for example, the AWGN channel with σ_{z} specified by a given Signal-To-Noise Ratio (SNR), with an equal number of positive examples (d=1) and negative examples (d=0) in each batch. The overall hyperparameters used for training the perm2vec permutation embedding engine 110 and the permutation classifier 112 g( ) are depicted in Table 1 below.

TABLE 1

| Symbol | Definition | Values |
|---|---|---|
| Iᵣ | Learning Rate | 10⁻³ |
| — | Optimizer | Adam |
| d_{w} | Input Embedding Size | 80 |
| dₚ | Output Embedding Size | 80 |
| — | LeakyReLU Negative Slope | 0.1 |
| — | SNR Range [dB] | 1-7 |
| K | Mini-batch Size | 5000 |
| — | Number of Mini-batches | 10⁵ |

Moreover, as described herein before, the node2vec node embeddings model 210 may be trained over the Tanner graph of the error correction code of length n to learn the representation of each variable node vᵢ thus resulting with n vector representations of length d_{w} for each variable node vᵢ which may serve as variable node embeddings. The hyperparameters used for the training the node2vec node embeddings model 210 be defined as known in the art optionally modified to define, for example, number of random walks 2000, walk length 10, neighborhood size 10 and node embedding dimension d_{w}=80.

Each of the training samples mapping a respective one of the plurality of training permutations may be labeled with a label associating the respective training permutation with a receptive one of the encoded codeword(s) transmitted and received via the transmission channel.

The label of each of the training permutations may further indicate whether the receptive training permutation was successfully decoded or not. Decoding the training permutations in order to label them and create the training dataset may be done using one or more decoders such as the decoder 106 employing the decoding algorithm dec( ) to decode each of training permutations and compute a cross-entropy loss for each of one or more received encoded codewords y according to equation 14 below.

$$L = - {\sum }_{π} [ {d}_{y , π} log ( p ( y , π ) ) + ( 1 - {d}_{y , π} ) log ( 1 - p ( y , π ) ) ] \qquad Equation 14$$

where d_{y,π}=1 if decoding of π(y) was successful under permutation otherwise d_{y,π}=0.

The training samples of the training dataset may therefore contains pairs of a permuted codeword (y,π) together with a corresponding label d_{y,π}.

The training dataset may be divided to a train subset, a test subset and optionally a validation subset as known in the art. In particular, in order to prevent overfitting, each of the train subset, the test subset and the validation subset may include a respective independent and uncorrelated subset of the training permutations corresponding to different one or more training codewords.

Optionally, the training encoded codeword may encode the zero codeword. For example, the training permutations included in the train subset may be permutations of the zero codeword. Using the zero codeword to train the neural networks based pre-decoder 108 may not degrade the performance of the trained neural networks based pre-decoder 108 since, based on empirical observations, error rates of the zero codeword may be similar to error rates of other chosen transmitted codewords for most if not all decoders 106, for example, the BP based decoder.

Nonetheless, the test subset may be composed of randomly chosen binary codewords c∈C which as empirically shown had no degradation in performance.

As shown at 504, the trainer 620 may train the neural network based pre-decoder 108 using the training dataset.

The training may include two steps, a first step 504A for training the perm2vec permutation embedding engine 110 and a step 504B for training the permutation classifier 112 g( ).

In 504A, the perm2vec permutation embedding engine 110 may be trained to compute a plurality of permutation embedding vectors for the plurality of training permutations as described herein before. In 504B for the permutation classifier 112 g( ) may be trained to compute the decode score for each training permutation as described herein before based on the classification of the respective permutation which may be classified based on the respective permutation, the embedding vector(s) computed for the respective permutation and the syndrome S as described herein before.

While they may be each trained separately, the perm2vec permutation embedding engine 110 and the permutation classifier 112 g( ) may be trained jointly since they may both use the same training dataset and they are interrelated with each other, specifically the permutation classifier 112 g( ) needs the output of the perm2vec permutation embedding engine 110, i.e., the permutation embedding vectors for classifying the training permutations.

It should be noted that since the perm2vec permutation embedding engine 110 may depend solely on a given permutation per codeword, all embeddings may be computed once and stored in memory. Then, at test time, determination of \hat{π} depends on the latency of n log₂(n+1) parallelizable forward-passes of the permutation classifier 112 g( ).

During training, the neural network based pre-decoder 108, specifically the neural network(s) of the perm2vec permutation embedding engine 110 and/or the neural network(s) of the permutation classifier 112 g( ) may learn, evolve and/or adjust according to a match (comparison) between the decode score computed for each training permutation and the decoding result of the respective training permutation as indicated in the label of the respective training permutation.

Optionally, the trainer 620 may train the neural network-based pre-decoder 108, specifically the permutation classifier 112 g( ) to classify the training permutation embedding vectors according to one or more of the additional features of the error correction code, for example, the permuted syndrome S representing an error pattern of a received codeword, the estimated Hamming Distance, the absolute value of the LLR, |l| and/or the like.

Optionally, the trainer 620 may train the neural network-based pre-decoder 108, specifically the permutation classifier 112 g( ) to classify the training permutation embedding vectors according to weights assigned to the plurality of permutations π based on knowledge base information relating to the error correction code which may be injected into the permutation classifier 112 g( ).

Optionally, the trainer 620 may train the neural network-based pre-decoder 108, specifically the perm2vec permutation embedding engine 110 according to the learned parameters matrices used to map the plurality of permutations to respective decode scores which may be derived and learned by the self-attentive layers of the perm2vec permutation embedding engine 110 as described herein before to map the distance distribution among the plurality of training permutations. Moreover, the trainer 620 may further train the neural network-based pre-decoder 108, specifically the perm2vec permutation embedding engine 110 according to biases further learned for the learned parameter matrices as described herein before.

The trainer 620 may then evaluate the performance of the neural network based pre-decoder 108, according to one or more performance parameters computed for the decode scores of the and/or their classification compared to their respective labels indicating whether these training permutations were successfully decoded or not. The performance parameters, as known in the art, may include, for example, accuracy, recall, precision, Area Under Curve (AUC)/Receiver Operating Characteristics (ROC) and/or the like. For example, the trainer 620 may evaluate and/or determine the performance of the neural network based pre-decoder 108 based on one or more thresholds predefined for one or more of the performance parameters.

As shown at 506, the training process 500 may be an iterative process comprising one or more training iterations each comprising selecting another training encoded codeword for training a neural network based pre-decoder 108. In particular, in case, the trainer 620 determines that the performance of the neural network based pre-decoder 108 is insufficient, for example, the threshold is not achieved for the performance parameter(s), the trainer 620 may initiate another iteration of the process 500 using another training encoded codeword.

As shown at 508, the trainer 620 may output the trained neural network based pre-decoder 108 which may be deployed to improve decoding performance and/or results of one or roe decoders such as the decoder 106. In particular, the trained neural network based pre-decoder 108 may be deployed to preprocess encoded codewords, including previously unseen codewords transmitted via the transmission channel before received by the decoder(s) 106 as described herein before. The neural network based pre-decoder 108 may further select a subset of one or more permutations having highest decode score and may forward the selected permutations to the decoder(s) 106 which may decode the selected permutation(s) with increased and typically significantly high success probability.

Optionally, the neural network based pre-decoder 108 may be further trained online after deployed to support decoding of one or more of the decoders 106. As such, each neural network based pre-decoder 108 may further train using one or more new and previously unseen encoded codewords of the error correction code transmitted over the specific transmission channel in which the neural network based pre-decoder 108 is deployed. This may allow the neural network based pre-decoder 108 to adapt, evolve and/or learn one or more interference patterns which may be specific to each specific transmission channel.

Performance of a decoder such as the decoder 106 decoding high success probability permutations selected by a trained neural network based pre-decoder such as the neural network based pre-decoder 108 (GPS) was evaluated through a set of experiments. Following are test results achieved by decoders 106 executing the decoding algorithm dec( ), specifically Belief Propagation (BP) and Weighted Belief Propagation (WBP) algorithms as known in the art to decode several short linear block codes, specifically BCH(31,16), BCH(63,36), BCH(63,45), BCH(127,64) and BCH(255,163).

The decoders 106 are tested with 5 BP iterations and the syndrome stopping criterion was adopted and checked after each iteration. The decoders 106 are based on the systematic parity-check matrices, H=[P^{T}|Iₙ₋ₖ] since these matrices are commonly used.

The BP decoder 106 decoding high success probability permutations selected by the neural network based pre-decoder 108 may be designated hereinafter by GPS+BP while the WBP decoder 106 decoding high success probability permutations selected by the neural network based pre-decoder 108 may be designated hereinafter by GPS+WBP.

The decoding performance is compared to the performance of baseline decoding performance where the BP and WBP decoders 106 are used to decode permutations selected according to legacy methods, specifically permutations randomly selected from the PG. The BP decoder 106 decoding randomly selected permutations may be designated random+BP hereinafter and respectively the WBP decoder 106 decoding randomly selected permutations may be designated random+WBP. In addition, the maximum likelihood results as known in the art are shown.

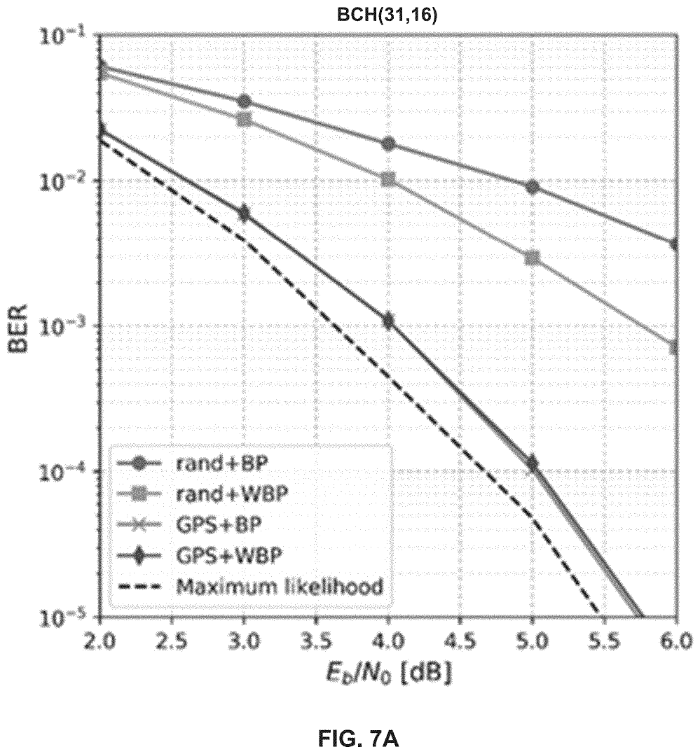

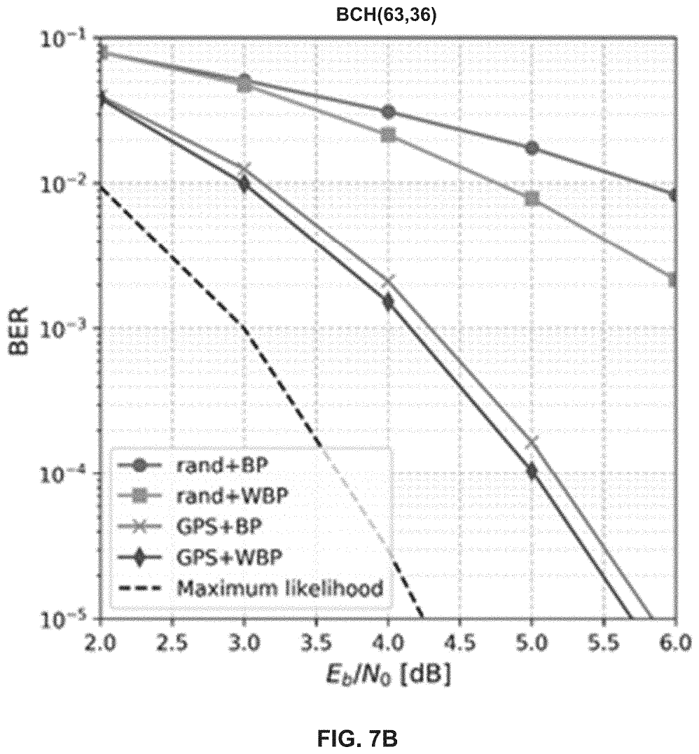

Reference is now made to FIG. 7A and FIG. 7B, which are graph charts of BER results vs. SNR for BCH(31,16) and BCH(63,36) codes decoded based on permutations selected by a neural network based pre-decoder vs. decoding based on legacy permutation selection, according to some embodiments of the present invention.

As seen, the performance and/or quality of decoding of the decoders 106 is assessed using the BER metric, for different SNR values [dB] after at least 1000 error codewords occurred. It should be noted that the SNR is referred to as the normalized SNR (E_{b}/N₀), which is commonly used in digital communication.

FIG. 7A presents the results of the GPS+BP, GPS+WBP, random+BP, random+WBP and the maximum likelihood for BCH(31,16) while FIG. 7B presents the results of the GPS+BP, GPS+WBP, random+BP, random+WBP and the maximum likelihood for BCH(63,36). Table 2 below further presents the performance results for the additional BCH codes showing the BER negative decimal logarithm for three SNR values [dB] where higher is better. The best results are highlighted in bold and the second-best results are underlined.

TABLE 2

| BCH (n, k) | random + BP | | | random + WBP | | | GPS + BP | | | GPS + WBP | | |
|---|---|---|---|---|---|---|---|---|---|---|---|---|
| SNR (dB) | 2 | 4 | 6 | 2 | 4 | 6 | 2 | 4 | 6 | 2 | 4 | 6 |

-TOP 1-

| | | | | | | | | | | | | |
|---|---|---|---|---|---|---|---|---|---|---|---|---|
| (31, 16) | 1.21 | 1.74 | 2.44 | 1.26 | 1.99 | 3.14 | 1.65 | 2.96 | 5.37 | 1.65 | 2.96 | 5.31 |
| (63, 36) | 1.10 | 1.51 | 2.08 | 1.10 | 1.67 | 2.66 | 1.40 | 2.67 | 5.23 | 1.42 | 2.82 | 5.44 |
| (63, 45) | 1.26 | 1.90 | 2.81 | 1.25 | 2.08 | 3.67 | 1.40 | 2.58 | 5.01 | 1.42 | 2.73 | 5.35 |
| (127, 64) | 0.99 | 1.30 | 1.74 | 0.99 | 1.32 | 2.11 | 1.01 | 1.94 | 4.04 | 1.01 | 1.98 | 1.41 |
| (255, 163) | 1.11 | 1.44 | 1.73 | — | — | — | 1.11 | 1.45 | 2.18 | — | — | — |

-TOP 5-

| | | | | | | | | | | | | |
|---|---|---|---|---|---|---|---|---|---|---|---|---|
| (31, 16) | 1.49 | 2.55 | 4.17 | 1.43 | 2.52 | 4.12 | 1.72 | 3.12 | 5.59 | 1.69 | 3.09 | 5.57 |
| (63, 36) | 1.18 | 2.04 | 3.36 | 1.18 | 2.12 | 3.84 | 1.47 | 2.96 | 5.78 | 1.49 | 3.11 | 6.07 |
| (63, 45) | 1.33 | 2.41 | 4.26 | 1.30 | 2.48 | 4.91 | 1.45 | 2.85 | 5.65 | 1.45 | 2.98 | 5.92 |
| (127, 64) | 0.99 | 1.49 | 2.66 | 0.99 | 1.51 | 2.88 | 1.01 | 2.10 | 4.62 | 1.02 | 2.11 | 4.70 |
| (255, 163) | 1.11 | 1.50 | 2.92 | — | — | — | 1.11 | 1.52 | 3.14 | — | — | — |

As evident from FIG. 7A, FIG. 7B and table 2, the GPS, i.e. the GPS+BP and the GPS+WBP outperform the examined baselines random+BP and random+WBP. For BCH(31,16) as seen in FIG. 7A, applying the GPS with BP may gain up to 2.75 dB compared to the random+BP and up to 1.8 dB over the random+WBP. Similarly, for BCH(63,36) as seen in FIG. 7B, the GPS+BP and GPS+WBP outperform the random+BP by up to 2.75 dB and by up to 2.2 dB with respect to random+WBP, respectively. A small gap may be observed between the GPS and the maximum likelihood lower bound. The maximal gaps are 0.4 dB and 1.4 dB for BCH(31,16) and BCH(63,36), respectively.

The performance was also measured and evaluated for selection of a group of top (top-k) highest decode score permutations.

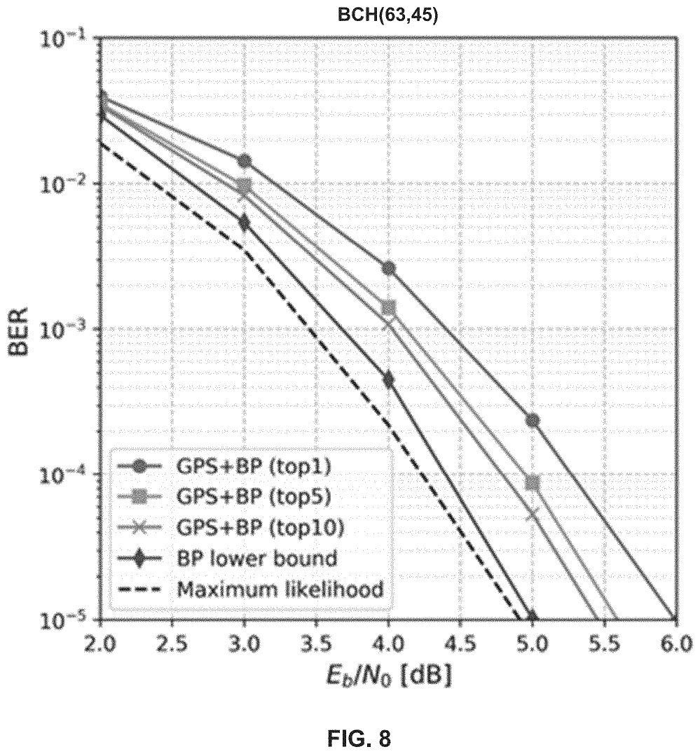

Reference is now made to FIG. 8, which is a graph chart of BER results BER results vs. SNR for top-k evaluations of BCH(63,45) code decoded based on permutations selected by a neural network based pre-decoder, according to some embodiments of the present invention.

In order to evaluate confidence of the GPS, performance of the decoder 106 decoding top-κ permutations was investigated. The top-κ permutations method may be considered as a list-decoder 106 with a smart permutation selection. This may extend equation 12 to the desired top-κ permutations where the selected codeword ĉ* may be chosen from a list of κ decoders 106 as expressed in equation 15 below.

ĉ*=arg max_{κ}∥y−ĉ_{κ}∥₂² Equation 15:

As seen in FIG. 8, presenting the results of the GPS+BP, the GPS+WBP, the random+BP, the random+WBP and the maximum likelihood, generally, better performance is observed as κ increases, with the added-gain gradually eroded.

Furthermore, as κ increases the empirical BP lower bound which may be achieved by decoding with a 5-iterations BP over all κ=n log₂(n+1) permutations and selecting the output codeword by the argmax criterion mentioned herein before.

As may be seen, an improvement of 0.4 dB may be observed between κ=1 and κ=5 and only 0.2 dB may be observed between κ=5 and κ=10. Furthermore, the gap between κ=10 and the BP lower bound is small, 0.4 dB. It should be noted that using the BP lower bound may be impractical since each random+BP/WBP may scale by O(n log n) while the GPS+BP/WBP may scale by only O(n). Specifically, the complexity of the permutation classifier 112 g( ) may scale by O(n) while the perm2vec permutation embedding engine 110 may scale by O(1) during inference (decoding).

Moreover, in the simulations, it was found that the latency for 5 BP iterations was 10-100 times greater for the random+BP/WBP compared to the GPS+BP/WBP inference.

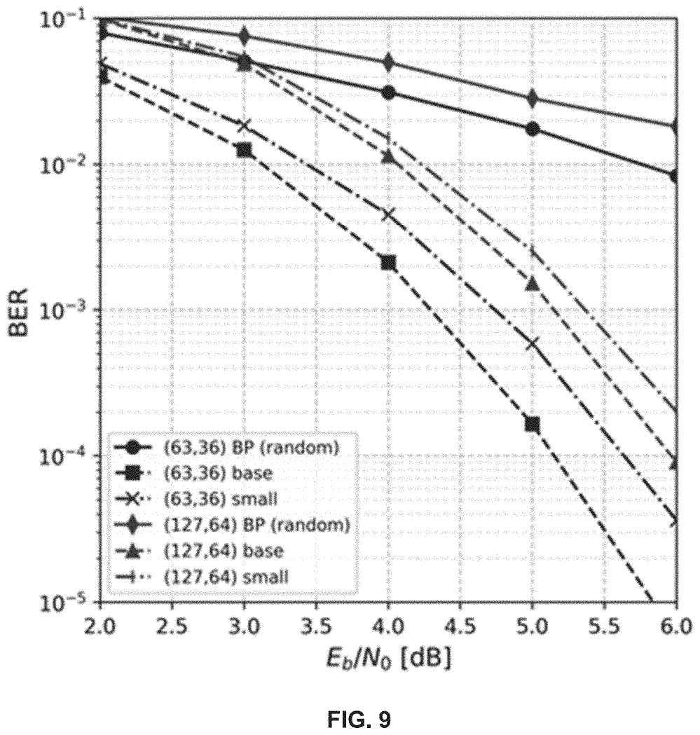

Reference is now made to FIG. 9, which is a graph chart of BER results vs. SNR for several BCH codes decoded based on permutations selected by a neural network based pre-decoder vs. legacy permutation selection for top-k evaluations, according to some embodiments of the present invention.

FIG. 9 presents performance of decoding permutations selected by the GPS using two embedding sizes compared to decoding the legacy randomly selected permutations. Specifically, the base GPS model which uses embedding size d_{q}=80 is compared to a smaller GPS model that uses embedding size d_{q}=20 (note that d_{q}=d_{w}). Changing the embedding size may also affect the number of parameters in e permutation classifier 112 g( ) as expressed in equation 8.

As seen, using a smaller embedding size causes a slight degradation in performance, but still dramatically improves the performance achieved by the legacy random+BP baseline. As may be observed, for the shorter BCH(63,36), the gap is 0.5 dB and for BCH(127,64) the gap is 0.2 dB.

Performance experiments were further conducted to evaluate different parity-check matrices.

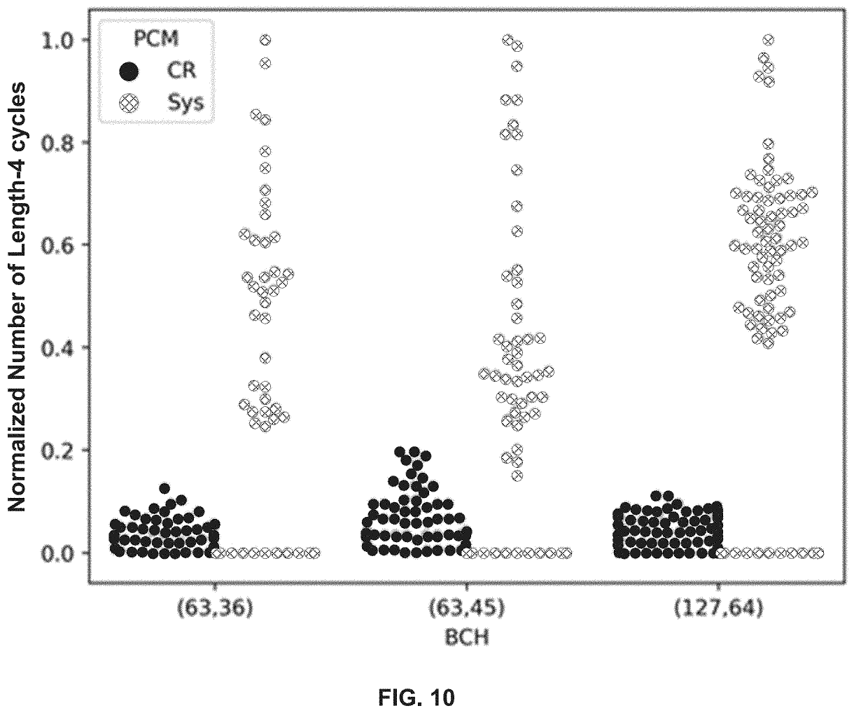

Reference is now made to FIG. 10, which is a graph chart presenting distributions of variable nodes of BCH(63,36), BCH(63,45) and BCH(127,64) codes encoded using cycle-reduced and systematic parity-check matrices and applied with a neural network based pre-decoder, according to some embodiments of the present invention.

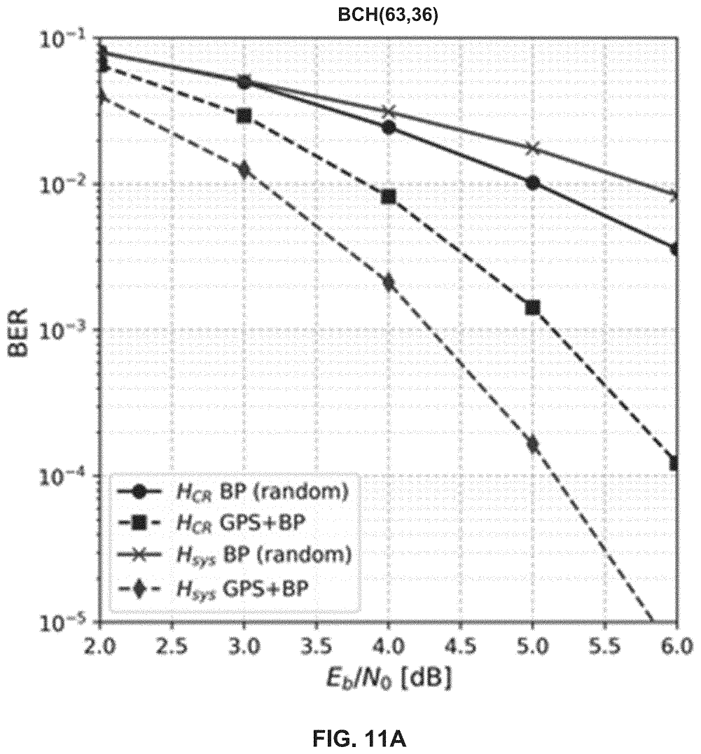

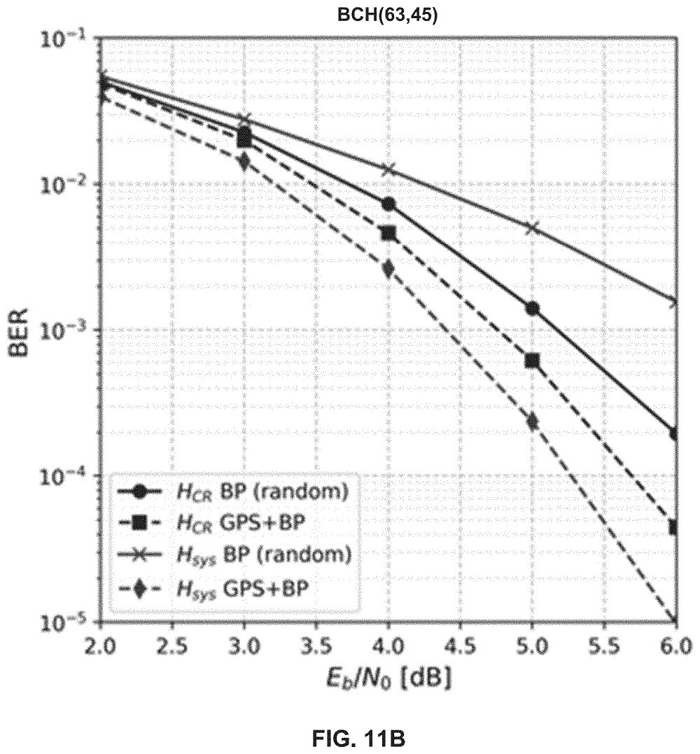

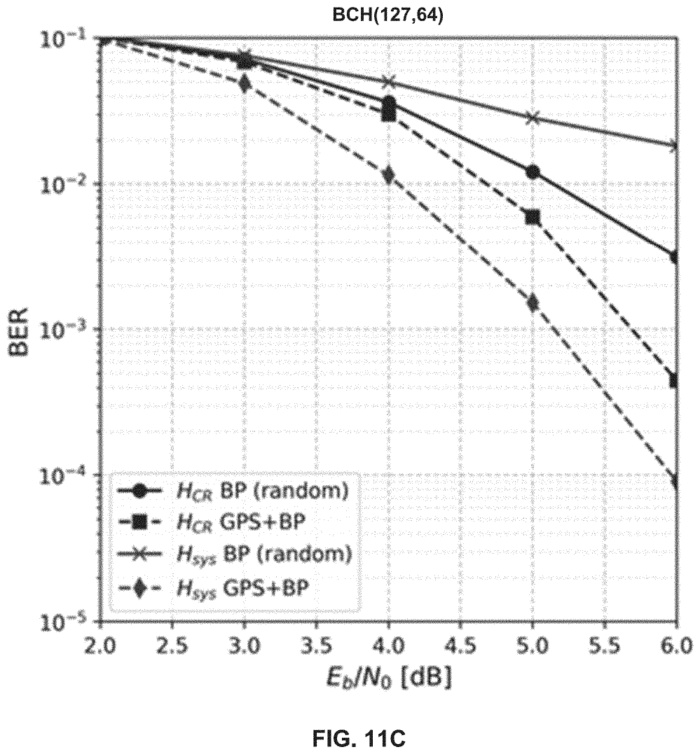

Reference is also made to FIG. 11A, FIG. 11B and FIG. 11C, which are graph charts of BER results vs. SNR for BCH(31,16) and BCH(63,36) codes BCH(63,36), BCH(63,45) and BCH(127,64) codes encoded using cycle-reduced and systematic parity-check matrices and decoded based on permutations selected by a neural network based pre-decoder, according to some embodiments of the present invention.

FIG. 10 depicts results for applying the GPS over two different parity-check matrices applied for BCH(63,36), BCH(63,45), and BCH(127,64) codes, a cycle-reduced H_{CR} (designated CR) and a systematic H_{sys} (designated Sys), both define the codes. By inspecting the number of length-4 cycles in the Tanner graphs induced by these matrices, substantial differences may be observed. While H_{CR} may induce a low amount of length-4 cycles evenly across all nodes, H_{sys} may induce an imbalanced distribution, the information bits have a high amount of length-4 cycles while the parity bits have none. It should be noted that each code was normalized by the following value (from left to right)—3042, 1022, and 20214.

As seen in FIG. 11A, FIG. 11B and FIG. 11C, the GPS may be able to exploit the structure of H_{sys} based parity-check matrix and outperform the H_{CR} based parity-check matrix by 0.75, 0.4 and 0.6 dB for BCH (63,36), (63,45), and (127,64), respectively.

An ablation study was also performed to analyze a number of facets of the perm2vec permutation embedding engine 110 and the permutation classifier 112 g( ) for BCH(63,36), BCH(63,45), and BCH(127,64). The BER was fixed to 10⁻³ and the SNR degradation of various excluded components was inspected with respect to the complete GPS model.

The ablation analysis was done for the perm2vec permutation embedding engine 110 and the permutation classifier 112 g( ) separately.

Regarding the permutation classifier 112 g( ), the complete permutation classifier 112 g( ) was evaluated against its three partial versions, namely the permutation embedding feature vector q_{π}, the permutation of the encoded codeword and the syndrome s′. Omitting the permutation embedding feature vector q_{π} from insertion to the permutation classifier 112 g( ) caused a performance degradation of 1.5 to 2 dB. It should be noted that the permutation π may still affect both l′ and s′. Excluding l′ or s′ caused a degradation of 1-1.5 and 2.5-3 dB, respectively. In addition, a simpler feature vector h=[q; l′; s′] was tried which led to performance degradation of 1 to 1.5 dB.

For ablating the perm2vec permutation embedding engine 110, the complete perm2vec permutation embedding engine 110 was compared against its two partial versions. Omitting the self-attention mechanism (sub-layer) decreased performance by 1.25 to 1.75 dB. Initializing the positional embedding in a random manner instead of using node embedding (node2vec 210) caused a performance degradation of 1.25 to 1.75 dB.

These results illustrate the advantages of the GPS implemented by the neural network based pre-decoder 108, and, as observed, the importance of the permutation embedding component. It should be noted that the total number of parameters is preserved after each exclusion for a fair comparison.

Finally, the performance was evaluated with respect to the number of BP Iterations.

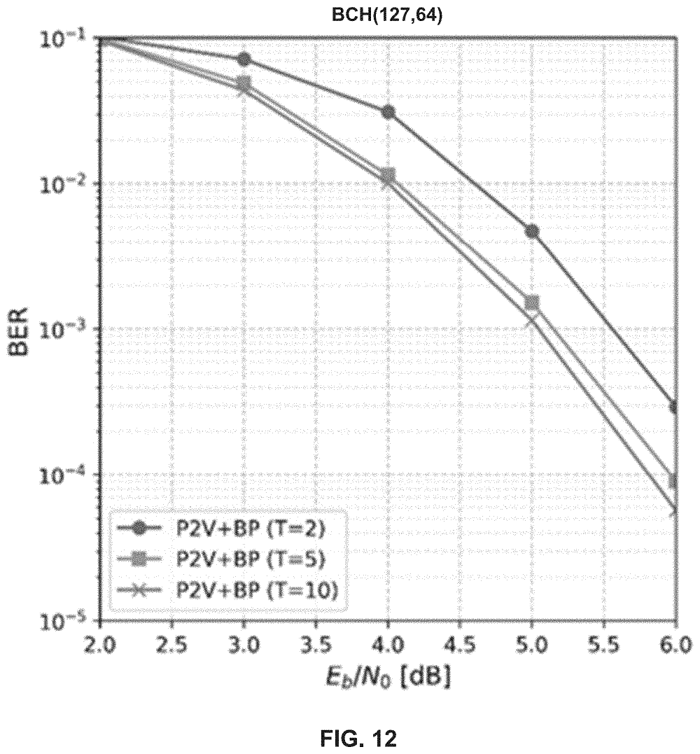

Reference is now made to FIG. 12, which is a graph chart of BER results BER results vs. SNR for a BCH(63,45) code decoded based on permutations selected by a neural network based pre-decoder trained in several training iterations, according to some embodiments of the present invention.

FIG. 12 presents performance results for training and applying the neural network based pre-decoder 108 on the different maximal number of BP iterations T∈{2,5,10}. As seen, increasing the number of iterations while applying early termination rule, for example, the syndrome-based termination, is likely to increase the overall performance, optionally at the cost of increased complexity. However, due to many short cycles in the Tanner graph, BP convergence is still not well understood.

As may be seen in FIG. 12, the neural network based pre-decoder 108 may gain the most in the first iteration. For BCH(127,64), 5 BP Iterations gain 0.4 dB over 2 BP iterations, while 10 iterations gain only 0.15 dB more. For shorter codes, T=10 did not improve the overall performance at all w.r.t T=5.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

It is expected that during the life of a patent maturing from this application many relevant systems, methods and computer programs will be developed and the scope of the terms error correction code and neural network are intended to include all such new technologies a priori.

As used herein the term “about” refers to ±10%.

The terms “comprises”, “comprising”, “includes”, “including”, “having” and their conjugates mean “including but not limited to”. This term encompasses the terms “consisting of” and “consisting essentially of”.

The phrase “consisting essentially of” means that the composition or method may include additional ingredients and/or steps, but only if the additional ingredients and/or steps do not materially alter the basic and novel characteristics of the claimed composition or method.

As used herein, the singular form “a”, “an” and “the” include plural references unless the context clearly dictates otherwise. For example, the term “a compound” or “at least one compound” may include a plurality of compounds, including mixtures thereof.

The word “exemplary” is used herein to mean “serving as an example, an instance or an illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals there between.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A neural network based pre-decoder, comprising:
a permutation embedding engine comprising at least one neural network trained to compute a plurality of permutation embedding vectors each for a respective one of a plurality of permutations of a received codeword encoded using an error correction code and transmitted over a transmission channel subject to interference;
a permutation classifier comprising at least one neural network trained to compute a decode score for each of the plurality of permutations based on classification of the plurality of permutation embedding vectors coupled with the plurality of permutations, the decode score expressing a probability of the respective permutation to be successfully decoded; and
a selection unit configured to output at least one selected permutation of the plurality of permutations of the received codeword having a highest decode score;
wherein at least one decoder is applied to recover the encoded codeword by decoding the at least one selected permutation.

2. The neural network based pre-decoder of claim 1, wherein the permutation embedding engine comprises at least one self-attention layer and head followed by a pooling layer.

3. The neural network based pre-decoder of claim 2, further comprising the at least one self-attention layer and head computes the plurality of permutation embedding vectors based on node embeddings of at least some of a plurality of nodes of a graph representation of the error correction code.

4. The neural network based pre-decoder of claim 3, wherein the node embeddings are computed by a neural network based node embedding model constructed based on graph representation of the error correction code, the neural network based node embedding model comprises a plurality of nodes and a plurality of edges connecting the plurality of nodes, each of the plurality of edges having a source node and a destination node is assigned with a respective weight adjusted during the training of the neural network based node embedding model.

5. The neural network based pre-decoder of claim 4, wherein the graph representation is a member of a group consisting of: a bipartite graph, a Tanner graph and a factor graph.

6. The neural network based pre-decoder of claim 2, wherein the permutation embedding engine comprising the at least one self-attention layer and head is trained to compute the plurality of permutation embedding vectors for the plurality of permutations based on a learned distance distribution among the plurality of permutations.

7. The neural network based pre-decoder of claim 1, wherein the permutation classifier is further configured to classify the plurality of permutation embedding vectors according to at least one additional feature of the error correction code, the at least one additional feature is a member of a group consisting of, a Hamming distance, a permuted syndrome and an absolute value of the log likelihood ratio (LLR) of the received encoded codeword.

8. The neural network based pre-decoder of claim 1, wherein the permutation classifier further comprises a multi-class classifier configured for simultaneously classifying at least a subset of the plurality of permutations in a single cycle.

9. A computer implemented method of using a trained neural network based pre-decoder to decode codes transmitted over transmission channels subject to interference, comprising:
receiving a codeword encoded using an error correction code and transmitted over a transmission channel subject to interference;
applying a trained neural network based pre-decoder to the encoded codeword, the trained neural network based pre-decoder is configured to;
compute a plurality of permutation embedding vectors each for a respective one of a plurality of permutations of the encoded codeword,
compute a decode score for each of the plurality of permutations based on classification of the plurality of permutation embedding vectors coupled with the plurality of permutations, the decode score expressing a probability of the respective permutation to be successfully decoded, and
output at least one selected permutation of the plurality of permutations having a highest decode score; and
applying at least one decoder to recover the encoded codeword by decoding the at least one selected permutation.

10. A computer implemented method of training a neural network based pre-decoder for preprocessing error correction codes transmitted over transmission channels subject to interference, comprising:
using at least one processor for:
receiving a plurality of permutations of at least one training codeword encoded using an error correction code and transmitted over a transmission channel subject to interference, each of the plurality of permutations is associated with a respective label associating the respective permutation with the at least one training encoded codeword and indicating whether it was successfully decoded;
training a neural network based pre-decoder to select at least one permutation of the at least one encoded codeword having highest probability to be successfully decoded by applying the neural network based pre-decoder to preprocess the at least one training encoded codeword by:
computing a plurality of permutation embedding vectors each for a respective one of the plurality of permutations of the at least one training encoded codeword,
classifying the plurality of permutation embedding vectors coupled with the plurality of permutations to compute a decode score for each of the plurality of permutations, the decode score expressing a probability of the respective permutation to be successfully decoded,
outputting at least one selected permutation of the plurality of permutations having a highest decode score, wherein the neural network based pre-decoder adjusts according to a match between the at least one selected permutations and its respective label; and
outputting the trained neural network based pre-decoder for selecting at least one of a plurality of permutations of at least one encoded codeword for decoding by at least one decoder.

11. The computer implemented method of claim 10, further comprising training the neural network-based pre-decoder to classify the plurality of permutation embedding vectors according to at least one additional feature of the error correction code, the at least one additional feature is a member of a group consisting of, a Hamming distance, a permuted syndrome and an absolute value of the log likelihood ratio (LLR) of the at least one training encoded codeword.

12. The computer implemented method of claim 10, further comprising training the neural network based pre-decoder to classify the plurality of permutation embedding vectors according to weights assigned to the plurality of permutations based on knowledge base information relating to the code.

13. The computer implemented method of claim 10, wherein the neural network based pre-decoder is trained to classify the plurality of permutation embedding vectors according to learned parameters matrices used to map the plurality of permutations to respective decode scores.

14. The computer implemented method of claim 13, wherein the neural network based pre-decoder is further trained to classify the plurality of permutation embedding vectors according to learned biases in the learned parameters matrices.

15. The computer implemented method of claim 10, wherein the at least one training encoded codeword encodes the zero codeword.

16. The computer implemented method of claim 10, wherein the training further comprising a plurality of training iterations, each iteration comprising selecting another training encoded codeword for training the training the neural network based pre-decoder.
